(19) United States
(12) Patent Application Publication
(10) Pub. No.: US 2025/0080059 A1
(43) Pub. Date: Mar. 6, 2025

(54) SWITCHED CAPACITOR POWER AMPLIFIER

(71) Applicant: Nordic Semiconductor ASA, Trondheim (NO)

(72) Inventors: Wayne WOO, Trondheim (NO); Carsten WULFF, Trondheim (NO); Dominik PRZYBOROWSKI, Trondheim (NO)

(73) Assignee: Nordic Semiconductor ASA, Trondheim (NO)

(21) Appl. No.: 18/825,976

(22) Filed: Sep. 5, 2024

(30) Foreign Application Priority Data
Sep. 6, 2023 (GB) 2313579.1

(51) Int. Cl. H03F 3/00; H03K 19/20

(52) U.S. Cl. CPC H03F 3/005; H03K 19/20; H03F 2200/294; H03F 2200/451

(57) ABSTRACT

A switched capacitor power amplifier comprising a first, positive signal path and a second, negative signal path. The switched capacitor power amplifier is arranged to receive a digital control signal and, based on the digital control signal, to selectively activate both the first signal path and the second signal path, in a differential mode, to provide a first peak output power level, or either the first signal path or the second signal path, to produce a second peak output power level, wherein the second peak output power level is lower than the first output power level.

### CROSS REFERENCE TO RELATED APPLICATION

This application claims priority from Great Britain Application No. 2313579.1, filed Sep. 6, 2023, which application is incorporated herein by reference in its entirety.

### TECHNICAL FIELD

The present invention relates to a switched capacitor power amplifier, a circuit portion for a radio transceiver, and a method of operating a switched capacitor power amplifier.

### BACKGROUND OF THE INVENTION

Radio communication devices typically utilise one or more antennas in order to transmit and/or receive radio signals. In order to effectively utilise these antennas, radio transceivers typically include RF front-end circuitry, operable at radio frequencies, to amplify any signals received from the antenna(s) and amplify signals for transmission using the antenna(s). Devices capable of both transmission and reception usually include a receive chain and a transmit chain, with front-end circuitry acting as the first stage in the receive chain and acting as the final stage in the transmit chain.

Radio signals generated internally by earlier stages in the transmit chain typically have low amplitude/power, and thus it is important to amplify these internally generated signals before feeding them to an antenna for transmission. Front-end radio circuitry typically includes power amplifiers for this purpose: power amplifiers are used to amplify internally generated radio signals in order to drive an antenna.

Radio frequency transmitter circuitry is generally most efficient when it is operating at its maximum output power setting, and becomes less efficient when operated at lower output powers. Solutions are known which allow improvement of efficiency at lower output powers. However, known solutions are complex and require additional hardware, and in some cases an additional power domain. The Applicant has recognised a need to provide an improved solution to achieve programmable output power.

### SUMMARY OF THE INVENTION

From a first aspect, the invention provides a switched capacitor power amplifier; comprising:
a first, positive signal path; and
a second, negative signal path;
wherein the switched capacitor power amplifier is arranged to receive a digital control signal and, based on the digital control signal, to selectively activate:
   both the first signal path and the second signal path, in a differential mode, to provide a first peak output power level; or
   either the first signal path or the second signal path, to produce a second peak output power level, wherein the second peak output power level is lower than the first output power level.

From a second aspect, the invention provides a method of operating a switched capacitor power amplifier, comprising a first, positive signal path and a second, negative signal path, the method comprising:
receiving, by the switched capacitor power amplifier, a digital control signal; and
selectively activating, based on the digital control signal:
   both the first signal path and the second signal path, in a differential mode, to provide a first peak output power level; or
   either the first signal path or the second signal path, to produce a second peak output power level, wherein the second peak output power level is lower than the first output power level.

Thus it will be seen that, in accordance with the invention, the switched capacitor power amplifier is selectively operable in either a differential mode of operation, producing a higher peak power, or in a single-end mode of operation, producing a lower peak power (i.e. achieving power back-off). By selectively activating either both signal paths (in a differential mode) or only one of the signal paths (in a single-end mode of operation) different levels of peak power output can be simply and efficiently achieved for the switched capacitor power amplifier. It will be appreciated that it is the achievable peak output power (i.e. the maximum output power, rather than the instantaneous output power) of the switched capacitor power amplifier that is varied by selective activation of one or both signal paths. As detailed further below, the power output by the switched capacitor power amplifier (i.e. at a particular instant in time) may be controlled by controlling individual components within the switched capacitor power amplifier (e.g. within each signal path). It will be appreciated that the switched capacitor power amplifier is switchable, over time (i.e. back and forth), between both of the modes of operation.

In some embodiments, the switched capacitor power amplifier is arranged to selectively activate (only) the first signal path (i.e. to disable or deactivate the second signal path) to produce the second peak output power level, wherein the first signal path has a higher efficiency than the second signal path. It will be appreciated that the switched capacitor power amplifier may likewise be arranged to selectively actively (only) the second signal path, and the second signal path may have a higher efficiency than the first signal path. Selecting the more efficient signal path to be activated during single-end operation (i.e. when producing lower peak power) advantageously improves the efficiency of the switched capacitor power amplifier operating in this mode as compared to its operation in differential mode. It will be appreciated that the efficiency of the signal paths may also refer to the efficiency of the downstream path elsewhere in the device to which that signal path is connected (e.g. the efficiency of the pathway which connects the first/second signal path to an antenna). It will be appreciated that a lower (back-off) output power, lower than the peak output power of the single activated signal path, is achievable both by operating the switched capacitor power amplifier in the differential mode (in the known manner), or by activating only one signal path. Where the one signal path that is operated is the more efficient of the two signal paths, this allows the back-off output power to be achieved with higher efficiency than if the differential mode of operation is used.

As described above, both the first signal path and the second signal path are operated in a differential mode to provide the first (higher) peak output power level. In some embodiments, selectively activating both the first signal path and the second signal path, in a differential mode, to provide a first peak output power level comprises supplying a first control signal (e.g. a time-varying control signal) to the first signal path, and supplying a second control signal (e.g. a time-varying control signal) to the second signal path, wherein the second control signal is the inverse of the first control signal (i.e. so as to supply differential input signals). The first control signal and the second control signal may be derived from, related to, or independent of the digital control signal. The digital control signal referred to above may affect only deactivation of one of the signal paths (i.e. the selective activation), and a separate control signal (or signals), such as a digital switching signal, may control operation of the signal paths (e.g. control how they operate when they are activated).

In some embodiments, activating a respective signal path comprises supplying a further (i.e. power-level) digital control signal to the respective signal path, the digital control signals comprising a digital control word which controls the output power level (e.g. by controlling which of the switching devices and therefore which corresponding capacitors are activated). Where both signal paths are activated, this may comprise supplying the same digital control signal to each of the first signal path and the second signal path (i.e. such that the same proportion of switching devices are activated in each, so each produces the same power level).

In some embodiments selectively activating either the first signal path or the second signal path, to produce the second peak output power level, comprises deactivating the first signal path by supplying a first inactive control signal to the first signal path wherein the first inactive control signal is a signal having constant value, or deactivating the second signal path by supplying a second inactive control signal to the second signal path wherein the second inactive control signal is a signal having constant value (i.e. such that only one, single-ended, activation signal is supplied). Thus, there is no switching occurring in the deactivated signal path (i.e. in whichever of the first signal path and the second signal path is not activated), and therefore no RF signal is produced by the non-activated signal path. The first/second inactive control signal may be the digital control signal, or may be supplied based on the digital control signal. Thus, the signal paths may be activated based, indirectly, on the digital control signal (rather than their operation being controlled directly by the digital control signal).

In some embodiments, the first signal path comprises at least two first-signal-path switching devices, and at least one first-signal-path capacitor, wherein the first-signal-path switching devices are arranged to switch, responsive to a (first) digital switching signal, so as to charge and discharge the at least one first-signal-path capacitor, and thereby produce a power-amplified output signal. In some embodiments, the first signal path comprises at least two first-signal-path capacitors. The at least two switching devices which together control a corresponding capacitor may be referred to as a set of switching devices (i.e. such that one set together controls one capacitor). The first signal path may comprise a plurality of such sets of switching devices each with a corresponding capacitor. In some embodiments, the first signal path comprises at least two sets of first-signal-path switching devices, wherein each set of first-signal-path switching devices are arranged to switch, responsive to a (first) digital switching signal, so as to charge and discharge a corresponding one of the least two first-signal-path capacitors, and thereby produce a power-amplified output signal.

In some embodiments, the at least two first-signal-path switching devices (or sets of first-signal-path switching devices) are selectively activatable to control a power output of the first signal path. This will (at least partially) control the power output of the switched capacitor power amplifier. It will be appreciated that the switching devices are only selectively activatable provided that (i.e. when) the first signal path is activated. It will furthermore be understood that by controlling individual switching devices (or pairs or sets of switching devices) of the signal path, the power output produced by that path at a given instant can be controlled. If only some of the (pairs/sets of) switching devices (and therefore their respective corresponding capacitors) are activated the output power will be lower than the peak output power. If all of the switching devices (and therefore all of the capacitors) in the signal path are activated, then the output power of the switched capacitor power amplifier will be either the first peak output power level or the second peak output power level, depending on which mode the switched capacitor power amplifier is operated in.

In some embodiments, selectively activating the second signal path comprises deactivating the first signal path by deactivating all of the at least two first-signal-path switching devices (i.e. all of the sets of switching devices) and/or by deactivating all of the (e.g. at least two) first-signal-path capacitors.

The switching devices may be transistors. In some embodiments, a (first) switching device of the at least two first-signal-path switching devices (or sets) is a PMOS transistor. In some embodiments, a (second) switching device of the at least two first-signal-path switching devices (or sets) is an NMOS transistor. The first signal path may comprise pairs (or multiple pairs) of such switching devices, each pair (or multiple pairs) corresponding to a respective capacitor.

Where it is the second signal path that is selectively activated (and therefore the first signal path that is selectively deactivated), selectively activating the second signal path may comprise deactivating the first signal path by applying a (first) inactive control signal, having a constant value, to a gate terminal of each of the at least two first-signal-path switching devices.

The statements made above in relation to the first signal path may apply likewise to the second signal path. Thus, in some embodiments, the second signal path comprises at least two second-signal-path switching devices, and at least one second-signal-path capacitor, wherein the second-signal-path switching devices are arranged to switch, responsive to a (second) digital switching signal, so as to charge and discharge the at least one second-signal-path capacitor, and thereby produce a power-amplified output signal. In some embodiments, the second signal path comprises at least two second-signal-path capacitors. The second signal path may comprise a plurality of sets of switching devices each with a corresponding capacitor. In some embodiments, the second signal path comprises at least two sets of second-signal-path switching devices, wherein each set of second-signal-path switching devices are arranged to switch, responsive to a (second) digital switching signal, so as to charge and discharge a corresponding one of the least two second-signal-path capacitors, and thereby produce a power-amplified output signal.

In some embodiments, the at least two second-signal-path switching devices (or sets of second-signal-path switching devices) are selectively activatable to control a power output of the second signal path. This will (at least partially) control the power output of the switched capacitor power amplifier. It will be appreciated that the switching devices are only selectively activatable provided that (i.e. when) the second signal path is activated. It will furthermore be understood that by controlling individual switching devices of the signal path (and therefore their corresponding capacitors), the power output produced by that path at a given instant can be controlled. If only some of the switching devices (and their corresponding capacitors) are activated the output power will be lower than the peak output power. If all of the switching devices in the signal path are activated, then the output power of the switched capacitor power amplifier will be either the first peak output power level or the second peak output power level, depending on which mode the switched capacitor power amplifier is operated in.

In some embodiments, selectively activating the first signal path comprises deactivating the second signal path by deactivating all of the at least two second-signal-path switching devices (i.e. all of the sets of switching devices, e.g. and therefore all capacitors in the second signal path). This differs from selectively deactivating a subset of the switching devices, to control the power output level, since that signal path ceases to make any output and therefore the switched capacitor power amplifier is no longer operated in a differential mode. Moreover, any inefficiencies introduced by the (sometimes deactivated) pathway are avoided when (i.e. during the period of time for which) that pathway is deactivated.

The switching devices may be transistors. In some embodiments, a (first) switching device of the at least two second-signal-path switching devices (or sets) is a PMOS transistor. In some embodiments, a (second) switching device of the at least two second-signal-path switching devices (or sets) is an NMOS transistor.

Where it is the first signal path that is selectively activated (and therefore the second signal path that is selectively deactivated), selectively activating the first signal path may comprise deactivating the second signal path by applying a (second) inactive control signal, having a constant value, to a gate terminal of each of the at least two second-signal-path switching devices. It will be appreciated that in addition (or alternatively) to this digital control signal, which deactivates the second signal path, a (separate or related) digital control signal (e.g. the digital switching signal) may be applied to the first signal path, in order to activate it (e.g. to control its operation) to produce the desired signal and/or achieve the desired power output level.

The first signal path or the second signal path may be deactivated (such that only the remaining signal path is selectively active) using any suitable arrangement. As described above, selective deactivation may be achieved by applying a constant signal (e.g. voltage) to the gates of all transistor switching devices in the signal path—this prevents any switching and therefore any charging or discharging of the capacitor, and thus does not produce any output signal. A constant control signal may be applied in any suitable manner, e.g. by simply changing the control signal that is applied, or by blocking a varying control signal, e.g. by opening a switch. Thus, one or more switches or logic gates may be used to (selectively, i.e. sometimes) deactivate the chosen signal path. Thus, in some embodiments, the switched capacitor power amplifier comprises at least one switch and/or logic gate arranged to (selectively) deactivate either the first signal path or the second signal path.

As described further below, the switched capacitor power amplifier may be used particularly advantageously within a radio-frequency front end, i.e. to amplify internally generated radio signals in order to drive an antenna. The switched capacitor power amplifier may thus be a switched capacitor radio-frequency power amplifier (i.e. arranged to operate in the radio frequency range). Thus, according to a third aspect of the invention, there is provided a (e.g. transmitter) circuit portion (e.g. a radio frequency front end) for a radio transceiver (or for a radio transmitter), the circuit portion comprising a switched capacitor power amplifier as described above. As explained, the switched capacitor power amplifier may be arranged to drive a radio-frequency antenna of the circuit portion for transmission, i.e. for wireless communication as in Bluetooth, WiFi or cellular communication systems.

In some embodiments, the circuit portion further comprises a transformer comprising: a primary winding comprising a first terminal for connecting to an antenna; and a secondary winding comprising a first terminal and a second terminal. In some embodiments, the circuit portion further comprises a low-noise amplifier circuit portion. The low-noise amplifier circuit portion may be connected to both the primary winding (e.g. to the first terminal of the primary winding) and to the second terminal of the secondary winding.

In some embodiments, the first, positive signal path of the switched capacitor power amplifier is connected to the first terminal of the secondary winding and the second, negative signal path of the switched capacitor power amplifier is connected to the second terminal of the secondary winding. As a result, the efficiency of the path through the first terminal will be higher than the efficiency of the path through the second terminal (which is loaded by the low-noise amplifier). Thus, advantageously the switched capacitor power amplifier may be arranged to selectively activate the first signal path to produce the second peak output power level. Selective activation of only the first signal path, where a lower output power (i.e. below the peak power of the first signal path) is sufficient, avoids introducing the inefficiencies which are present on the second signal path due to the receiver circuitry.

In some embodiments, the circuit portion further comprises a processor. The processor may be arranged to supply the digital control signal to the switched capacitor power amplifier. It may also be arranged to supply the digital switching signal referred to above and/or the first and/or second control signals (or inactive control signals) also referred to above.

Features of any aspect or embodiment described herein may, wherever appropriate, be applied to any other aspect or embodiment described herein. Where reference is made to different embodiments or sets of embodiments, it should be understood that these are not necessarily distinct but may overlap. It will furthermore be understood that references made to a device “arranged to” or “configured to” carry out a step correspondingly extend to a method comprising such a step, and vice versa.

### BRIEF DESCRIPTION OF THE DRAWINGS

An embodiment of the invention will now be described, by way of example only, with reference to the accompanying drawings, in which:

FIG. 1 is a schematic diagram showing a radio-frequency front end according to an embodiment of the present invention;

FIG. 2 is a schematic diagram showing an example switched capacitor power amplifier according to an embodiment of the invention;

FIG. 3 is a schematic diagram showing another example switched capacitor power amplifier according to an embodiment of the invention;

FIG. 4 is a graph showing power out from a switched capacitor amplifier according to the invention along the x-axis, compared to efficiency along the y-axis; and

FIG. 5 is a graph showing power out from a switched capacitor amplifier according to the invention along the x-axis, compared to power consumption along the y-axis.

### DETAILED DESCRIPTION

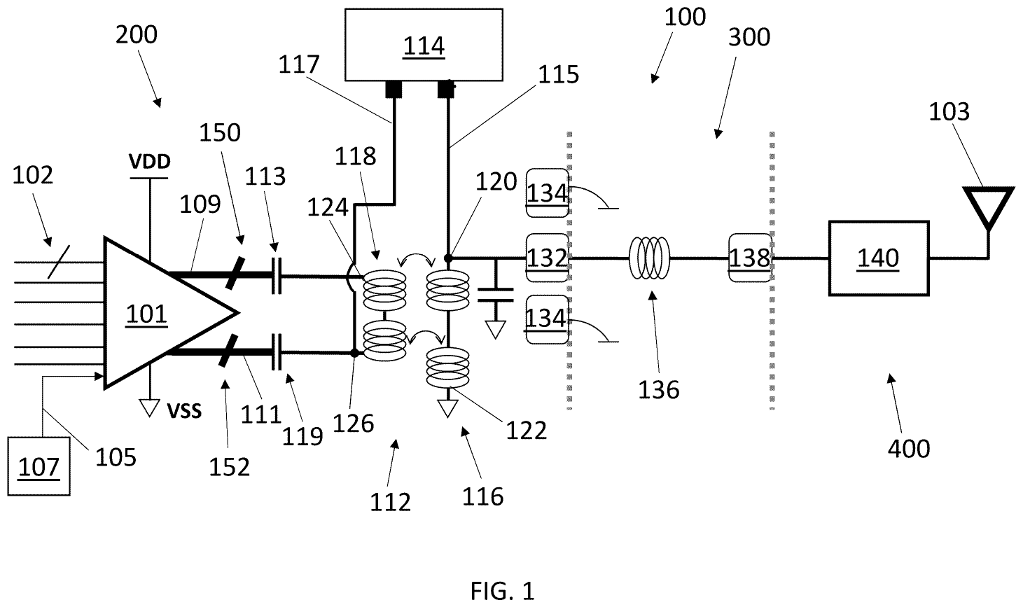

FIG. 1 is a schematic diagram showing a radio-frequency (RF) front end 100, including a switched capacitor power amplifier (SCPA) 101 according to the present invention.

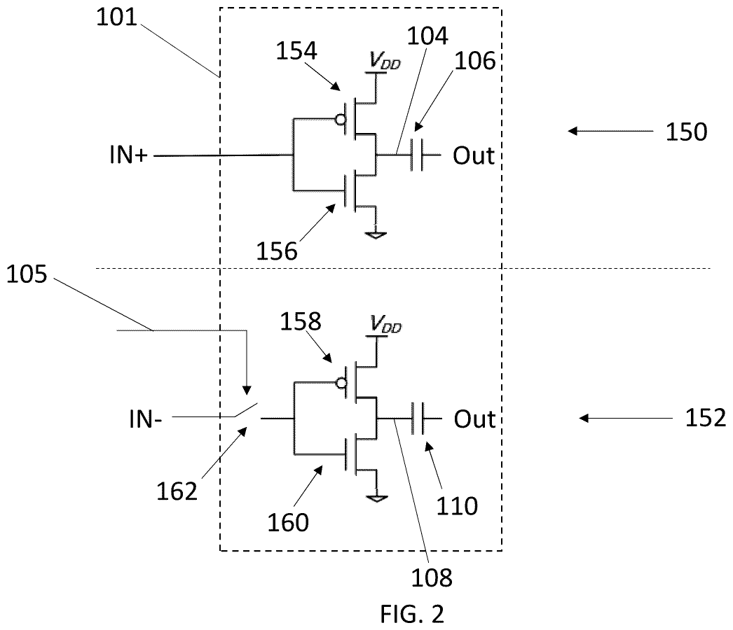

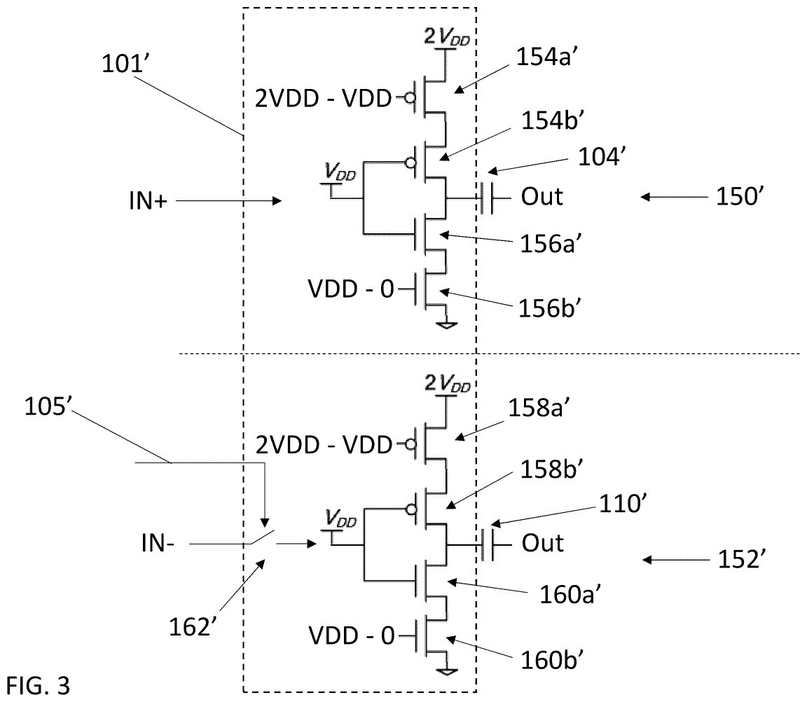

The SCPA 101 receives a first plurality of digital control signals 102, and a second digital control signal 105. The SCPA 101 is connected by a first plurality of wires 109 (represented as a single bus) to a corresponding first plurality of capacitors, which all share a common node on one side (the right side with reference to the view of FIG. 1). This plurality of capacitors is represented for simplicity as a single capacitor 113, connected on its left side to the plurality of wires 109 and on its right side to a single wire, which connects to a first terminal 124 as discussed below. The SCPA 101 similarly includes a second plurality of wires 111 (a second output bus) connected to a second plurality of capacitors, which are represented as a single capacitor 119. The SCPA 101 is described in greater detail below with reference to FIGS. 2 and 3.

The RF front end 100 further includes a transformer 112 (e.g. a balun transformer) and a low-noise amplifier circuit portion 114. The low-noise amplifier circuit portion 114 is for use when the RF front end 100 is operating in the reception mode. The purpose of the low-noise amplifier circuit portion 114 is to amplify received radio signals (which typically have very low amplitude/power) whilst introducing minimal additional noise in order keep the signal-to-noise ratio (SNR) of the amplified signal as close as possible to that of the signal initially received at the antenna 103.

The transformer 112 comprises a primary winding 116 and a secondary winding 118. The transformer 112 may be integrated as part of e.g. a system-on-chip (SoC), or it may comprise its own distinct component(s) which may be connected or attached to e.g. a printed circuit board (PCB). The primary winding 116 comprises a first terminal 120 at a first end thereof and a second terminal 122 at a second end thereof. The secondary winding 118 comprises a first terminal 124 at a first end thereof, a second terminal 126 at a second end thereof.

The first terminal 120 of the primary winding 116 is connected to the antenna 103 and thus transmits/receives a voltage signal thereto/therefrom in dependence on whether the transceiver (of which the RF front end 100 is a part) is operating in the transmission mode or reception mode. The second terminal 122 of the primary winding 116 is connected to ground. A first terminal 115 of the low-noise amplifier circuit portion 114 is also connected to the first terminal 120 of the primary winding 116, and thus also receives the voltage signal from the antenna 103 when the RF front end 100 is operating in the reception mode. A second terminal 117 of the LNA circuit portion 114 is connected to the second terminal 126 of the secondary winding 118.

The common node of the first plurality of capacitors 113 is connected to the first terminal 124 of the secondary winding 118. The common node of the second plurality of capacitors 119 is connected to the second terminal 126 of the secondary winding 118. Since the LNA circuit portion 114 is also connected to the second terminal 126 of the secondary winding 118, this path, from the second plurality of wires 111, which define a second output path of the SCPA 101, is loaded, whereas the (first) path including the first plurality of wires 109 is not, giving rise to an asymmetry.

The purpose of the transformer 112 is to combine RF power generated by the first and second signal path and to improve impedance matching between the antenna 103, the LNA 114 and the SCPA 101, thereby improving the SNR of both received and transmitted radio signals. The impedance matching is improved since the impedance of the primary winding 116 can be more closely matched to that of the antenna 103, and the impedance of the secondary winding 118 can be more closely matched to that of the SCPA 101, than if no transformer were included between the SCPA 101 and the antenna 103.

When the RF front-end 100 transmits a radio signal, a first voltage signal is generated by the first plurality of capacitors 113, based on the received digital control signals 102. At the same time, a second voltage signal is generated by the second plurality of capacitors 119 of the SCPA 101. The SCPA 101 is a differential power amplifier, meaning that (when it is operated in the differential mode of operation) the second voltage signal and the first voltage signal have equal and opposite amplitudes (i.e. they are in antiphase with equal amplitude), and thus the signal for transmission consists of the difference between the first and second voltage signals. These two differential voltage signals are then fed to the first and second terminals 124, 126 respectively of the secondary winding 118, thereby inducing an oscillating magnetic field in the secondary winding 118.

The oscillating magnetic field within the secondary winding 118, generated by the SCPA 101, induces an antiphase oscillating magnetic field within the primary winding 116. This in turn induces a voltage across the primary winding 116 that is in antiphase relative to the voltage across the secondary winding 118 generated by the power amplifier. The ratio of the amplitudes of the voltage across the secondary winding 118 and the voltage across the primary winding 116 is determined by a number of different factors, including the ratio of the number of coils included in the primary and secondary windings 116, 118, the core used for the transformer 112, etc.

The induced voltage across the primary winding 116 of the transformer 112 is then fed to the antenna 103 via the first terminal 120 of the primary winding 116, via a number of other components as described below. As a result, the antenna 103 then transmits the radio signal.

The RF front-end 100 further includes an ESD protection pad 132, as well as two down bonds 134 (e.g. copper or gold wire) for RF signal shielding, which extend off the chip domain 200 (to the left of the dashed line in FIG. 1) and onto the package domain 300, between the two dashed lines. The down bonds 134 shield the RF signal path from other potential disturbances by connecting the adjacent pads to the most quiet potential. Bondwire 136 (or any other package parasitic components) connects from the ESD protection pad 132 to a packaging pin 138. This is connected to matching circuitry 140, which is then connected to the antenna 103. The matching circuitry 140 and the antenna 103 are located on the circuit board, i.e. in the board domain 400.

FIG. 2 shows a first example SCPA 101 according to the present invention in greater detail.

The SCPA 101 includes a first, positive signal path 150, including the first plurality of wires 109 which each supply signals to their respective capacitors of the plurality of capacitors 113, so as to produce an output. FIG. 2 shows a single wire 104 of the plurality of wires 109, connected to a single (first) capacitor 106 of the plurality of capacitors. The SCPA 101 further includes a second, negative signal path 152. It includes a single wire 108 of the second plurality of wires 111, connected to a single (second) capacitor 110.

This first capacitor 106 (and likewise the second capacitor 110) are each a capacitor in an associated capacitor array 113, 119 of the signal path 150, 152 with each capacitor corresponding to a set of switching devices. In other words, one capacitor for each signal path is illustrated in FIG. 2, together with its corresponding switching devices. The SCPA 101 includes a plurality of such arrangements (i.e. sets of switching devices with their corresponding capacitors) in each signal path, with all the capacitors of the first signal path 150 sharing a common node on the “out” side, and similarly all the capacitors of the second signal path 152 sharing a common node on their “out” side. The capacitors will thus be understood as being located at an output of the SCPA 101.

The first signal path 150 includes a PMOS device 154 and an NMOS device 156. The bottom plate of the first capacitor 106 is connected to the drain of the PMOS device 154 and to the drain of the NMOS device 156. The source of the NMOS device 156 is connected to the ground. The source of the PMOS device 154 is connected to the supply voltage Vdd. The gates of both the PMOS device 154 and the NMOS device 156 are controlled by an input signal (e.g. voltage), referred to in FIG. 2 as IN+, which controls the output signal that is produced. The digital control signals 102 include a digital control word which controls which of the switching devices 154, 156 (and therefore which corresponding capacitors) are activated. In other words, this controls the active/inactive array ratio of the capacitors and thereby controls the output power level. Inactive capacitors are held at a fixed potential (e.g. ground), e.g. with the control signal IN+ or IN− for that capacitor as a flat direct current (DC) signal with 0 Hz frequency. Active capacitors are controlled to switch at a carrier frequency which is controlled by the input signal IN+, e.g. IN+/IN− for an active capacitor may be a complementary square wave. The carrier frequency is determined by an input clock. When the SCPA 101 is operated in a differential mode, the control word is the same for both signal paths (with the RF signal being in an antiphase relationship), such that the same number of sets of switching devices and corresponding capacitors are activated in each signal path.

The PMOS device 154 and the NMOS device 156, which together control the first capacitor 106, form a set of switching devices.

Similarly, the second signal path 152 includes a PMOS device 158 and an NMOS device 160 (together forming a set of switching devices). The bottom plate of the second capacitor 110 is connected to the drain of the PMOS device 158 and to the drain of the NMOS device 160. The source of the NMOS device 160 is connected to the ground. The source of the PMOS device 158 is connected to the supply voltage Vdd. The gates of both the PMOS device 158 and the NMOS device 160 are controlled by an input signal (e.g. voltage), referred to in FIG. 2 as IN−, which is the inverse of the input signal for the first signal path 50.

As described with reference to FIG. 1, when the SCPA 101 is operated in the differential mode, the SCPA 101 produces outputs on both of its signal paths 150, 152, and these are combined to give a greater amplitude signal than if only one of the signal paths was used (i.e. in a single-end mode of operation).

If all capacitors are active (i.e. all sets of switching devices are being switched), a peak output power of the SCPA 101 is achieved. By deactivating some (i.e. a subset of) capacitors (by deactivating some sets of switching devices) in each of the first signal path 150 and the second signal path 152, a power output that is lower than the peak output power achievable by the SCPA 101 may be achieved.

In addition to the digital control signals 102, which control the output power level, the SCPA 101 according to the present invention is further configured to receive a second digital control signal 105 from a processor 107. This digital control signal 105 is supplied, in particular, to the second signal path 152. The digital control signal 105 controls a switch 162. It will be appreciated that although not illustrated in FIG. 1, the first digital control signals 102 may also be received from a processor (e.g. possibly the same processor 107 as the second digital control signal 105).

The digital control signal 105 is used to control activation or deactivation of the (entire) second, negative signal path 152 (i.e. of all the sets of switching devices). If the digital control signal 105 has a value which activates the second signal path 152, then the supplied signal closes the switch 162 and the control signal IN− is applied to the (active) transistors of the second signal path 152, i.e. when operated in a differential mode, the amplifier receives differentials inputs (i.e. differential control signals). Alternatively, if the digital control signal 105 has a value which deactivates the second signal path 152, then the supplied signal opens the switch 162 and the control signal IN− is no longer applied to the transistors of the second signal path 152, i.e. when only one of the two signal paths is activated (in the single-ended mode of operation) a single-ended input is received (i.e. a single control signal). Rather the gates of the transistors are connected to a constant potential.

It will be appreciated that this effect may be achieved by any suitable mechanism which is able to hold the gates of all transistors of the second signal path 152 at a constant potential. For example, it may be achieved by the digital control signal 105 causing the input control signal IN− to be altered so that it is a signal with a constant potential. Alternatively, appropriate logic gates may be used to achieve this effect.

One alternative example is that the input signal IN− may be set to “high”, i.e. Vdd, and the supply voltage Vdd may be pulled down to 0V, Vss or GND (ground, the lowest potential of the circuit). Thus, in some examples, the digital control signal 105 may be the “high” IN-signal or may cause this “high” signal to be supplied, and may also cause the supply voltage to be pulled down as described. Thus, the switch 162 need not necessarily be included.

The effect of operating the SCPA 101 in single-end mode is that a lower peak power is achieved than operation in the differential mode-specifically the peak power is halved.

Thus, digital control signals control both the number of capacitors that are activated (i.e. switched), out of the whole set, and also, if operating in a single-end mode, which signal path is inactive.

As discussed above, the LNA 114 is connected to the second terminal 126 of the secondary winding 118, resulting in higher parasitic loading on the path that is supplied by the second, negative signal path 152 of the SCPA 101. As a result, the negative signal path 152 is the less efficient of the two signal paths of the SCPA 101. Thus, even though in practice either signal path of the SCPA 101 could be deactivated, as described above, in order to achieve an SCPA 101 having a lower peak power, it is particularly advantageous that in the described embodiment it is the second, negative path 152 which is deactivated, since this improves the efficiency of the SCPA 101 when operated in single-end mode.

FIG. 3 shows a second example SCPA 101′, which may be used in place of the SCPA 101 in the embodiment of FIG. 1. Like components have been labelled with the same reference numerals as used in FIG. 2, but followed by an apostrophe. This Figure illustrates all of the transistors in parallel, i.e. as is the case where the digital control signal 102 activates all capacitors, and therefore in which the SCPA 101′ is producing an output power equal to its peak output power.

In this example, the first, positive signal path 150′ includes two PMOS devices 154a′, 154b′ and two NMOS devices 156a′, 156b′, although in other examples more than two PMOS and NMOS devices may be present, corresponding to each capacitor of the plurality of capacitors. These together provide a set of switching devices, controlling a corresponding capacitor. Similarly, the second, negative signal path 152′ includes two PMOS devices 158a′, 158b′ and two NMOS devices 160a′, 160b′ (together providing a set). These are respectively connected across a voltage difference of 2V_{dd} (i.e. double the supply voltage as for the example SCPA 101 of FIG. 2). This provides a higher output power than the SCPA 101 of FIG. 2.

As described above, inactivation of one of the signal paths (e.g. the less efficient, negative signal path 152′) may be achieved in any suitable manner. For example, inactivation may be achieved by one or more of: switching off the voltage supply to the inactive side, switching off an RF clock source of the inactive side, disabling the driver input (IN+/IN−) to the inactive side by providing this control signal to combinational logic gates such as a NAND gate or OR gate.

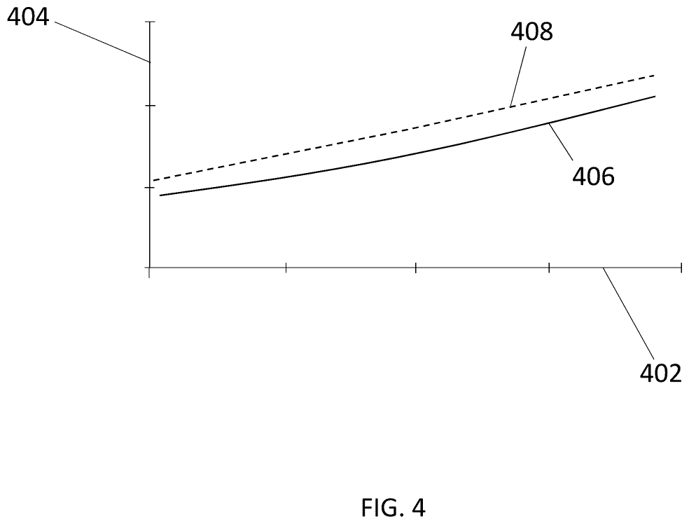

FIG. 4 is a graph showing power out (in decibel milliwatts, dBm) from the SCPA 101 along the x-axis 402, compared to efficiency (expressed as a percentage) of the SCPA 101 along the y-axis 404. The solid line 406 represents operation of the SCPA 101 in differential mode, and the dashed line 408 represents operation of the SCPA 101 in the single-end mode of operation, in particular the single-end mode of operation in which the less efficient pathway of the SCPA 101 is disabled. As described above, power output for the SCPA 101 may be varied (in both the differential mode of operation and the single-end mode) by selectively deactivating certain capacitors of the SCPA 101 (e.g. using a control word). By doing so (e.g. by selecting appropriate, different, digital control words for the differential mode and the single-end mode of operation), the SCPA 101 may achieve (approximately) the same output power values in both modes, for the range illustrated in the graph of FIG. 4, since these values are below the peak power for both modes of operation. Generally, a higher value control word (activating a greater proportion of the capacitors) will be needed to achieve an (instantaneous) output power value for the single-end mode, than is used to achieve the same output power in differential mode. It can be seen that across all power output values the SCPA 101 has greater efficiency operating in the single-end mode (with only one path, the more efficient path, active) than in the differential mode. This is advantageous since it is often the case for known devices that efficiency is lower at lower peak powers. Although not shown, if the less efficient pathway of the SCPA 101 (including the second plurality of capacitors 119) were enabled, and the more efficient pathway (including the first plurality of capacitors 113) were disabled, this would produce a dashed line on the graph of FIG. 4 which is below the solid line 406, i.e. less efficient than either the described single-end operation or the differential operation.

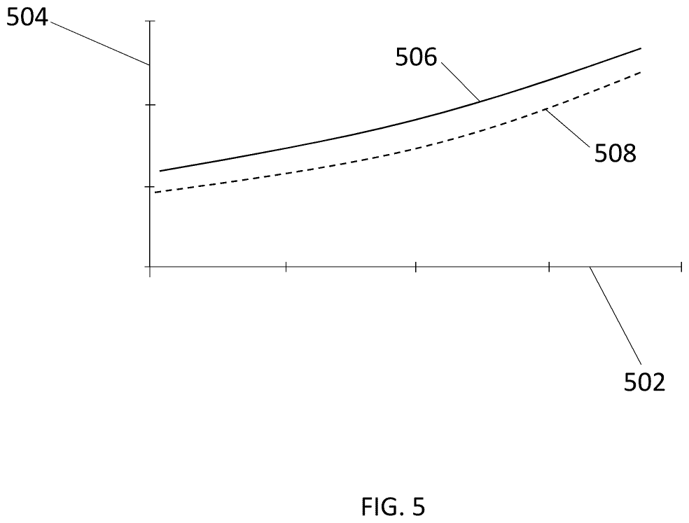

FIG. 5 is a graph showing power out (again in dBm) from the SCPA 101 along the x-axis 502, compared to power consumption of the SCPA 101, in units of mW, shown along the y-axis 504. Again, the solid line 506 represents operation of the SCPA 101 in differential mode, and the dashed line 508 represents operation of the SCPA 101 in the single-end mode of operation in which the less efficient pathway of the SCPA 101 is disabled. It can be seen that single-end operation uses less power to achieve the same output power, as compared to differential operation (i.e. single-end operation achieved according to the invention is more efficient than the differential operation).

1. A switched capacitor power amplifier; comprising:
a first, positive signal path; and
a second, negative signal path;
wherein the switched capacitor power amplifier is arranged to receive a digital control signal and, based on the digital control signal, to selectively activate:
both the first signal path and the second signal path, in a differential mode, to provide a first peak output power level; or
either the first signal path or the second signal path, to produce a second peak output power level, wherein the second peak output power level is lower than the first output power level.

2. The switched capacitor power amplifier of claim 1, wherein the switched capacitor power amplifier is arranged to selectively activate the first signal path to produce the second peak output power level, wherein the first signal path has a higher efficiency than the second signal path.

3. The switched capacitor power amplifier of claim 1, wherein selectively activating both the first signal path and the second signal path in a differential mode to provide a first peak output power level comprises supplying a first control signal to the first signal path, and supplying a second control signal to the second signal path, wherein the second control signal is the inverse of the first control signal.

4. The switched capacitor power amplifier of claim 1, wherein selectively activating either the first signal path or the second signal path, to produce the second peak output power level, comprises deactivating the first signal path by supplying a first inactive control signal to the first signal path wherein the first inactive control signal is a signal having constant value, or deactivating the second signal path by supplying a second inactive control signal to the second signal path wherein the second inactive control signal is a signal having constant value.

5. The switched capacitor power amplifier of claim 1, wherein the second signal path comprises at least two second-signal-path switching devices, and at least one second-signal-path capacitor, wherein the second-signal-path switching devices are arranged to switch, responsive to a digital switching signal, so as to charge and discharge the at least one second-signal-path capacitor, and thereby produce a power-amplified output signal.

6. The switched capacitor power amplifier of claim 5, wherein the at least two second-signal-path switching devices are selectively activatable to control a power output of the second signal path.

7. The switched capacitor power amplifier of claim 5, wherein selectively activating the first signal path comprises deactivating the second signal path by deactivating all of the at least two second-signal-path switching devices.

8. The switched capacitor power amplifier of claim 5, wherein a first switching device of the at least two second-signal-path switching devices is a PMOS transistor, and wherein a second switching device of the at least two second-signal-path switching devices is an NMOS transistor.

9. The switched capacitor power amplifier of claim 8, wherein selectively activating the first signal path comprises applying an inactive control signal, having a constant value, to a gate terminal of each of the at least two second-signal-path switching devices.

10. The switched capacitor power amplifier of claim 1, further comprising at least one switch and/or logic gate arranged to deactivate either the first signal path or the second signal path.

11. A circuit portion for a radio transceiver, comprising a switched capacitor power amplifier as claimed in claim 1.

12. The circuit portion of claim 11, further comprising:
a transformer comprising:
a primary winding comprising a first terminal for connecting to an antenna; and
a secondary winding comprising a first terminal and a second terminal; and
a low-noise amplifier circuit portion connected to both the primary winding and to the second terminal of the secondary winding;
wherein the first, positive signal path of the switched capacitor power amplifier is connected to the first terminal of the secondary winding and wherein the second, negative signal path of the switched capacitor power amplifier is connected to the second terminal of the secondary winding.

13. The circuit portion of claim 12, wherein the switched capacitor power amplifier is arranged to selectively activate the first signal path to produce the second peak output power level.

14. The circuit portion of claim 11, further comprising a processor, wherein the processor is arranged to supply the digital control signal to the switched capacitor power amplifier.

15. A method of operating a switched capacitor power amplifier, comprising a first, positive signal path and a second, negative signal path, the method comprising:
receiving, by the switched capacitor power amplifier, a digital control signal; and
selectively activating, based on the digital control signal:
both the first signal path and the second signal path, in a differential mode, to provide a first peak output power level; or
either the first signal path or the second signal path, to produce a second peak output power level, wherein the second peak output power level is lower than the first output power level.
